(19) United States
(12) Patent Application Publication
(10) Pub. No.: US 2011/0278056 A1
(43) Pub. Date: Nov. 17, 2011

(54) MANUFACTURING METHOD OF PRINTED CIRCUIT BOARD UNIT, MANUFACTURING APPARATUS THEREOF, MANUFACTURING METHOD OF ELECTRONIC COMPONENT, AND ELECTRONIC COMPONENT

(75) Inventors: Shuichi TAKEUCHI, Kawasaki (JP); Kenji Kobae, Kawasaki (JP); Tetsuya Takahashi, Kawasaki (JP)

(73) Assignee: FUJITSU LIMITED, Kawasaki-shi (JP)

(21) Appl. No.: 13/083,815

(22) Filed: Apr. 11, 2011

(30) Foreign Application Priority Data
May 17, 2010 (JP) 2010-113115

(51) Int. Cl. H05K 1/09; H05K 3/30; B23K 1/20

(52) U.S. Cl. 174/261; 228/173.1; 29/832; 29/739

(57) ABSTRACT

A manufacturing method of a printed circuit board unit is provided. A portion of bumps which is arranged on an electronic component is pressed to lower heights of the portion of bumps as compared to other bumps.

### CROSS-REFERENCE TO RELATED APPLICATION

This application is based upon and claims the benefit of priority of Japanese Patent Application No. 2010-113115, filed on May 17, 2010, the entire contents of which are incorporated herein by reference.

### FIELD

Embodiments discussed herein are related to a manufacturing method of a printed circuit board, a manufacturing apparatus thereof, a manufacturing method of an electronic component, and an electronic component.

### BACKGROUND

High-performance electronic components, which are referred to as WLP (Wafer Level Package), BGA (Ball Grid Array) package, and CSP (Chip Size Package), are mounted on a printed circuit board. A plurality of bumps are arranged in a grid pattern on a substrate body of the electronic component. The bumps are formed as solder balls which can be molten by heating.

An electronic component is known, which 0.08 mm bumps in height are arranged at 0.25 mm pitches in a grid pattern formed on a 5 mm by 5 mm substrate body. In addition, a laminated electronic component which allows a 0.15 mm or less in thickness of the substrate body has been proposed.

Referring to FIGS. 11A and 11B, a conventional method for mounting an electronic component on a print circuit board will be described. As illustrated in FIG. 11A, a plurality of bumps 2a to 2e is arranged on a substrate body 2′ of an electronic component 1′. On the other hand, electrodes 12a to 12e are arranged on a board 11 of a printed circuit board 10.

When the electronic component 1′ is placed on the printed circuit board 10, the bumps 3a to 3e of the electronic component 1′ are respectively aligned to the electrodes 12a to 12e of the printed circuit board 10. Then, the electronic component 1′ and the printed circuit board 10 are heated in a reflow furnace to molten solder balls, i.e., the bumps 2a to 2e. Therefore, the bumps 2a to 2e of the electronic component 1′ are joined to the corresponding electrodes 12a to 12e of the printed circuit board 10, respectively. Thus, the electronic component 1′ can be mounted on the printed circuit board 10 (See, for example, JP-A-9-153513 and JP-A-10-13007).

However, in the above method for mounting an electronic component, a substrate body such as a package substrate is provided with an insulating layer for protecting a circuitry formed in the electronic component, and a redistribution (rewiring) layer for reducing the number of electrodes, for example.

During reflow process, difference in thermal expansion occurs between printed circuit board and an insulating layer and/or a redistribution layer, which causes a warping of the electronic component. Due to the warping of the electronic component, open solder defect (poor joint) can occur between the bump of the electronic component and the electrode of the printed circuit board.

For example, as illustrated in FIG. 11B, in case that a substrate body 2′ of an electronic component 1′ is upwardly warped during the reflow, outer bumps 2a and 2e is spaced away from the corresponding electrodes 12a and 12e of the printed circuit board 10, respectively. Therefore, open solder defect can occur between the bumps 2a and 2e of the electronic component 1′ and the electrodes 12a and 12e of the printed circuit board 10.

On the other hand, as illustrated in FIG. 12, in case that the substrate body 2′ of the electronic component 1′ is downwardly warped during the reflow, inner bumps 2b, 2c, and 2d is spaced away from the corresponding electrodes 12b, 12c, and 12d of the printed circuit board 10, respectively.

Therefore, open solder defect can occur between the bumps 2b, 2c, and 2d of the electronic component 1′ and the electrodes 12b, 12c, and 12d of the printed circuit board 10, respectively. In order to prevent the open solder defect in response to the warping of the electronic component, it has been proposed that the back surface of the electronic component is held under pressure by a mounting device during the reflow, and thus the warping of the electronic component is suppressed. In this case, however, mounting time increases.

### SUMMARY

According to an embodiment of the invention, a manufacturing method of a printed circuit board includes pressing a portion of bumps arranged on an electronic component to lower heights of the portion of bumps as compared to other bumps.

The object and advantages of the invention will be realized and attained at least by the elements, features, and combinations particularly pointed out in the claims. It is to be understood that both the foregoing general description and the following detailed description are exemplary and explanatory, and are not restrictive of the invention.

### BRIEF DESCRIPTION OF DRAWINGS

FIG. 1A is a cross-sectional view of the electronic component according to a first embodiment of the present invention, and FIG. 1B is a plan view thereof;

FIG. 2 is a cross-sectional view of the electronic component under a warping according to the first embodiment;

FIG. 3A schematically illustrates a printed circuit board unit under a reflow process not reaching the melting point of the bumps of the electronic component yet, and FIG. 3B schematically illustrates the printed circuit board unit under the reflow process after reaching the melting point of the bumps of the electronic component;

FIG. 4 is a flow chart illustrating a method for mounting an electronic component on a printed circuit board;

FIGS. 5A to 5G are diagrams illustrating a method for mounting an electronic component on a printed circuit board;

FIG. 6A and FIG. 6B are diagrams each illustrating the configuration of an electronic component according to a second embodiment, where FIG. 6A is a cross-sectional view of the electronic component and FIG. 6B is a plan view thereof;

FIG. 7A and FIG. 7B are diagrams illustrating joints between bumps of an electronic component and electrodes of a printed circuit board;

FIG. 8 is a plan view illustrating the configuration of an electronic component according to a third embodiment;

FIG. 9 is a plan view illustrating the configuration of an electronic component according to a fourth embodiment;

FIG. 10A is a diagram illustrating the configuration of an electronic- component mounting apparatuses and FIG. 10B is a diagram illustrating the configuration of an electronic-component manufacturing apparatus, respectively;

FIG. 11A and FIG. 11B are diagrams illustrating a conventional method for mounting an electronic component on a print circuit board; and

FIG. 12 is a diagram illustrating a state where a conventional electronic component is mounted on a print circuit board.

### DESCRIPTION OF EMBODIMENTS

Hereinafter, embodiments of a manufacturing method of a printed circuit board, a manufacturing apparatus thereof, a manufacturing method of an electronic component, and an electronic component will be described in details with reference to the attached drawings.

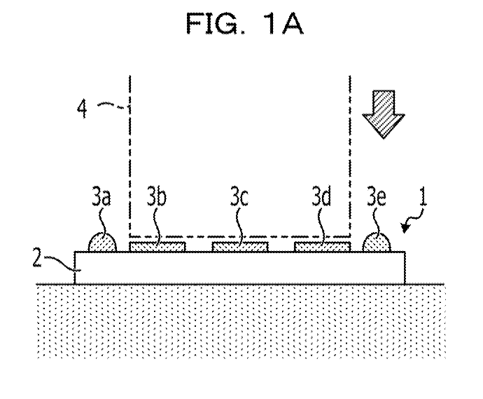

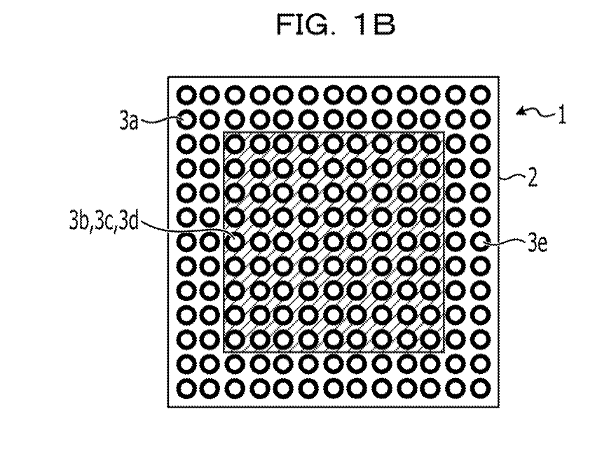

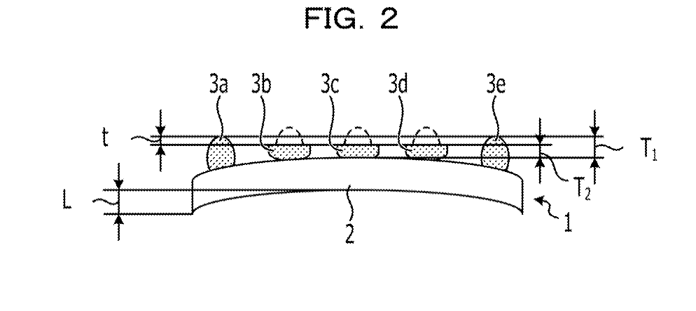

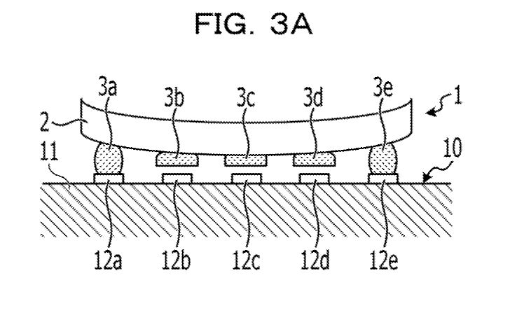

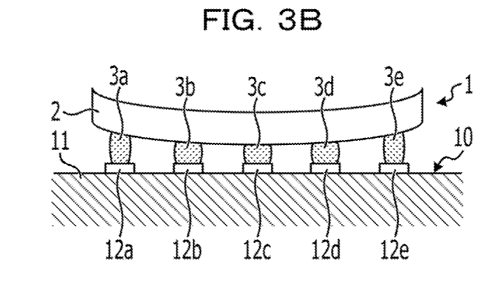

FIG. 1A and FIG. 1B illustrate an electronic component according to a first embodiment of the present invention. FIG. 1A is a cross-sectional view of the electronic component, and FIG. 1B is a plan view thereof. In addition, FIG. 2 is a cross-sectional view of the electronic component under a warping according to the first embodiment. FIG. 3A schematically illustrates a printed circuit board unit under a reflow process not yet reaching the melting point of the bumps of the electronic component. On the other hand, FIG. 3B schematically illustrates the printed circuit board unit under the reflow process after reaching the melting point of the bumps of the electronic component.

The first embodiment will be described under the conditions that, for example, the substrate body 2 of the electronic component 1 has 3 mm to 20 mm on a side. In the first embodiment, the solder balls forming the bumps 3a to 3e have approximately 0.08 mm in height, and 0.15 to 0.5 mm pitches between the adjacent bumps. It is noted that the present invention is not limited to such an exemplary configuration of the first embodiment.

In FIG. 1A and FIG. 1B, the electronic component 1 includes a plate-shaped substrate body 2. In addition, the bumps 3a to 3e are arranged in a grid pattern on a surface of the substrate body 2.

The peripheral region to be most upwardly warped in the substrate body 2 has outer bumps 3a and 3e of 0.08 mm in height thereon. On the other hand, the central region in the substrate body 2 has inner bumps 3b, 3c, and 3d of less than 0.08 mm in height thereon. Specifically, inner bumps 3b, 3c, and 3d have flattened top surfaces which are pressed by press mechanism (head) 4.

In the first embodiment, pressing is performed on the inner bumps 3b to 3d located at central region to lower their heights less than the outer bumps 3a and 3e located at peripheral region.

In case that the electronic component 1 is upwardly warped in a concave shape by application of heat as illustrated in FIG. 3, the inner bumps 3b, 3c, and 3d among the bumps 3a to 3e are subjected to a process for lowering their heights by a flattening-press using a press mechanism 4.

As illustrated in FIG. 2, when the maximum amount of warping of electronic component 1 is set to “L”, and the height of the outer bumps 3a and 3e is set to “T₁”, the heights of the inner bumps 3b, 3c, and 3d are lowered to “T₂” by pressing (Tᵢ >T₂). Therefore, as described later, an amount of warping can be absorbed by “t” which is substantially equal to “T₁ - T₂”.

The bumps 3b, 3c, and 3d are spherical in shape, and the volumes of these spherical bodies are not changed even if when the top surfaces of the bumps 3b, 3c, and 3d are flattened under vertical pressure applied by a press mechanism 4. In addition, the pressed bumps 3b, 3c, and 3d can be restored to former shapes by surface tension and thermal expansion at the time of melting by reflow, and thus the restored bumps 3b, 3c, and 3d are joined to the corresponding electrodes 12b, 12c, and 12d of the printed circuit board 10, respectively.

As illustrated in FIG. 3A, when the electronic component 1 is mounted on the printed circuit board 10, outer bumps 3a and 3e are solder balls which are not flattened by pressing. Thus, the bumps 3a and 3e can be brought into contact with the corresponding electrodes 12a and 12e of the printed circuit board 10, respectively.

On the other hand, in FIG. 3A, inner bumps 3b, 3c, and 3d have already been pressed to lower the height of the bumps 3b, 3c and 3d as compared to the outer bumps 3a and 3e. Therefore, the bumps 3b, 3c, and 3d are apart from the corresponding electrodes 12b, 12c, and 12d of the printed circuit board 10 until the bumps 3b, 3c, and 3d are melted.

Therefore, since the outer bumps 3a and 3e in contact with the electrodes 12a and 12e can reach their melting point, and become molten earlier than the inner bumps 3b to 3d due to heat transfer from the electrodes 12a and 12e, the peripheral region of the substrate body 2 which upwardly warps greater than the central region can be joined to the printed circuit board 10 via the outer bumps 3a and 3e earlier than the central region.

After the outer bumps 3a and 3e are molten, the inner bumps 3b to 3d become molten during the reflow and joined to the corresponding electrodes 12b to 12d. As a result, bumps 3a to 3e of the electronic component 1 and the corresponding electrodes 12a to 12e are joined to one another without solder-open defect.

In view of the melting temperatures of solder balls under application of heat, among solder balls to be used for the bumps 3a to 3e of the electronic component 1, the solder balls with melting temperatures lower than those of the bumps 3b, 3c, and 3d may be used for the bumps 3a and 3b. In this case, the solder balls of the bumps 3a and 3e located on the outer side of the substrate body 2 can be molten earlier than the solder balls of the bumps 3b, 3c, and 3d by application of heat. Therefore, the bumps arranged on the outer side can be quickly joined to each other.

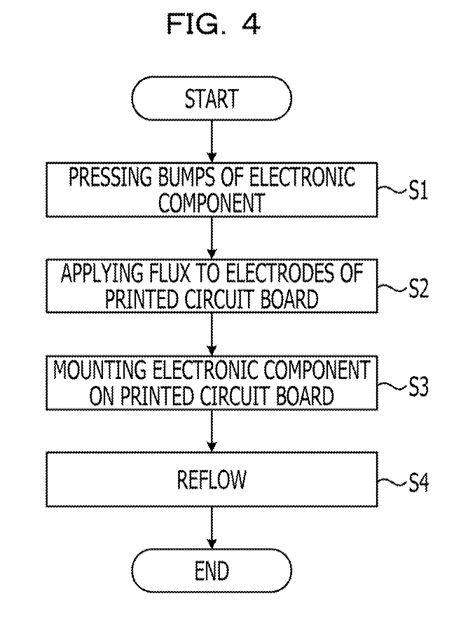

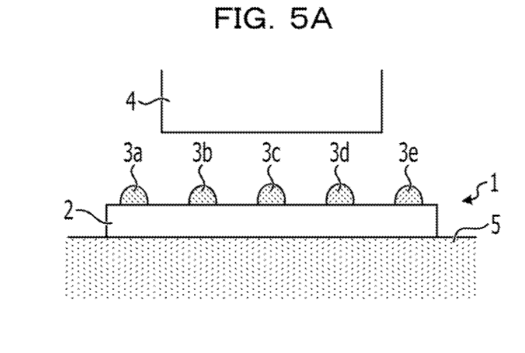

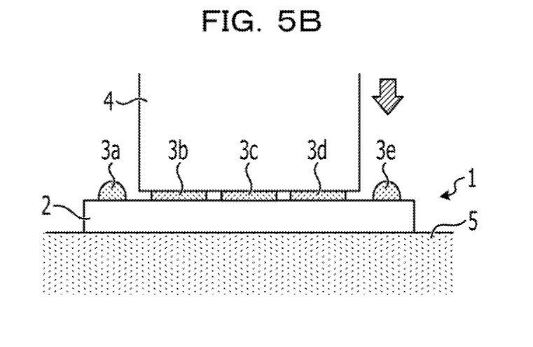

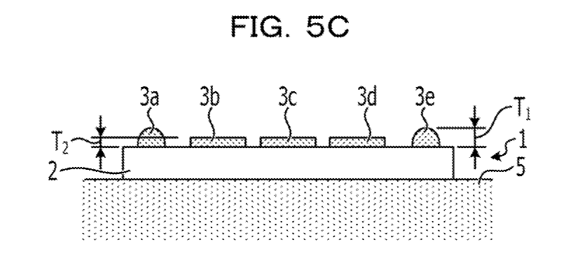

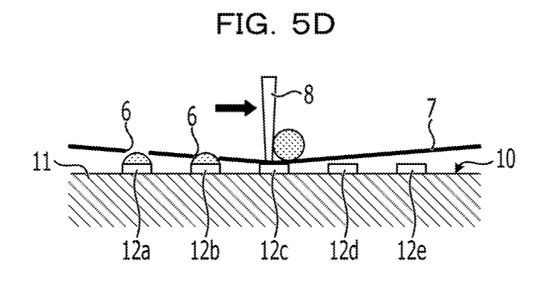

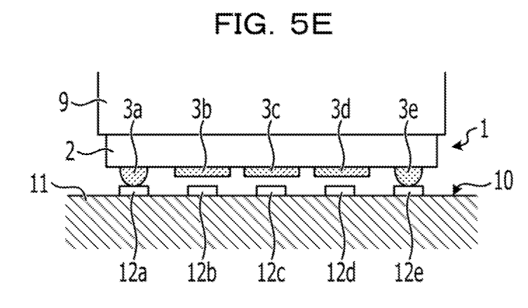

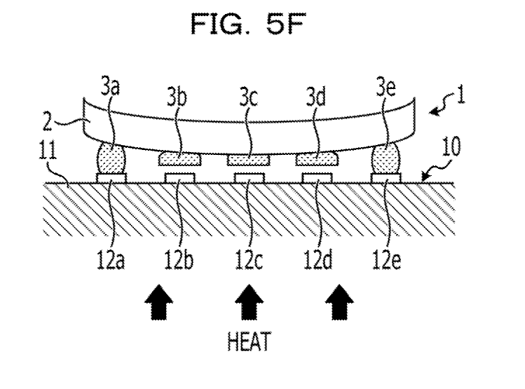

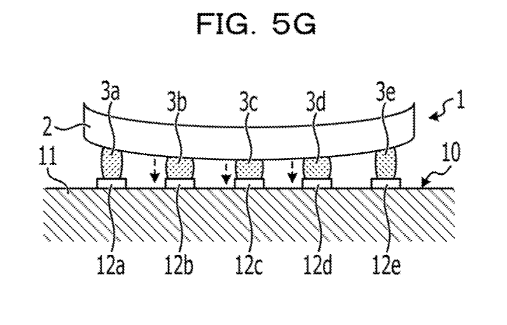

Referring now to FIG. 4 and FIGS. 5A to 5G, a procedure for mounting the electronic component 1 on the printed circuit board 10 will be described. FIG. 4 is a flow chart illustrating a method for mounting an electronic component on a printed circuit board. In addition, FIG. 5A to 5G are diagrams illustrating a method for mounting the electronic component on the printed circuit board.

Here, the electronic component 1 includes a substrate body 2 on which bumps 3a to 3e made of solder balls are arranged in a grid. Hereinafter, the printed circuit 10 will be described as one where electrodes 12a to 12e are arranged on the surface of a board 11. In actuality, a numerically-controlled (NC) surface-mounting apparatus or component-mounting apparatus is used for mounting the electronic component 1 on the printed circuit board 10.

As illustrated in a flow chart of FIG. 4, first, some of bumps 3a to 3e arranged on the substrate body 2 of the electronic component 1 are pressurized (Operation S1).

Specifically, as illustrated in FIG. 5A, the substrate body 2 of the electronic component 1 is placed on the upper part of a working stage 5. As illustrated in FIG. 5B, a press mechanism 4 is used for flattening the bumps 3b, 3c, and 3d, which are located at the center portion, among bumps 3a to 3e arranged on the substrate body 2 of the electronic component 1 to a specified height. As illustrated in FIG. 5C, the pressing with the press mechanism 4 reduces the heights of the bumps 3b, 3c, and 3d to be lower than the heights of the bumps 3a and 3e located on the outer side of the substrate body 2.

For example, if the height T₁ of each of the bumps 3a to 3e arranged on the substrate body 2 of the electronic component 1 is 0.08 mm (Tᵢ =0.08 mm), the bumps 3b, 3c, and 3d arranged on the center portion are flattened by pressing to a height of 0.03 mm (T₂ =0.03 mm). Therefore, the warping of the electronic component 1 produced when heating by reflow can be absorbed to a specified amount, for example, approximately 0.05 mm.

Flux is applied to the electrodes 12a to 12e of the printed circuit board 10 on which the electronic component 1 is mounted (Operation S2). Specifically, as illustrated in FIG. 5D, a paste cream is applied to the surfaces of the electrodes 12a to 12e of the printed circuit board 10 using a squeegee 8 through a stainless-steel metal mask 7 having a plurality of through-holes 6.

Here, as an alternative to a method for transferring the flux on the upper surface of the electrodes 12a to 12e of the printed circuit board 10 using the squeegee 8, a method for transferring the flux on the upper surface of the electrodes 12a to 12e of the printed circuit board 10 may be one for transferring the flux on the surfaces of the electrodes 12a to 12e using a plurality of pins to which the flux is being applied.

The electronic component 1 is mounted on the printed circuit board 10 (Operation S3). Specifically, as illustrated in FIG. 5E, it is mounted using a mounting head 9 while the electrodes 12a to 12e formed on the upper surface of the printed circuit board 10 face to the bumps 3a to 3e formed on the substrate body 2 of the electronic component 1.

The electronic component 1 and the printed circuit board 10 are reflow-heated (operation S4). The term “reflow” means a process for heating solder balls, which are the bumps 3a to 3e of the electronic component 1 from the lower part of the printed circuit board 10 on which the electrode component 1 is being mounted, using a reflow furnace at a specified temperature. By performing the reflow-heating, the solder balls that form the bumps 3a to 3e are heated and molten.

Specifically, as illustrated in FIG. 5F, the reflow heating is performed from the lower part of the printed circuit substrate 10 while the electronic component 1 is being mounted on the upper part of the printed circuit board 10. In this case, as illustrated in FIG. 5G, when comparing the bumps 3a and 3e with higher solder balls with the bumps 3b, 3c, and 3d with lower-height solder balls, the higher-height solder balls of the bumps 3a and 3e can melt faster than the lower-height solder balls of the bumps 3b, 3c, and 3d when the electronic component 1 is heated.

Therefore, the outer side of the substrate body 2, which is on the warping side of the electronic component 1, can be joined comparatively faster than the inner side thereof. The flattened solder balls of the bumps 3b, 3c, and 3d can be molten by application of heat over a period of time.

In other words, the thermal expansion and surface tension of the solder balls effect on the solder balls of the bumps 3b, 3c, and 3d arranged at the lower position are also molten to join to the electrodes 12b, 12c, and 12d on the printed circuit board 10, respectively. As a result, the bumps 3a to 3e of the electronic component 1 and the electrodes 12a to 12e are joined to each other with reduced joint failure, such as separation.

As described above, in the method for mounting an electronic component according to the first embodiment, the electronic component 1 to be mounted on the printed circuit board 10 includes bumps 3a and 3e having specified heights and being arranged at positions with larger amounts of warping on the substrate body 2. Furthermore, the electronic component 1 also includes the bumps 3b, 3c, and 3d which have been flattened by pressing so as to be lower than the heights of the bumps 3a and 3e, respectively. At the time of reflow-heating the electronic component 1, the bumps 3a and 3e, which are arranged on the portions to be warped greater than the portions of the bumps 3b, 3c, and 3d, can be molten faster than the bumps 3b, 3c, and 3d arranged on the portions to be warped less.

Therefore, the bumps 3a and 3e of the electronic component 1 are joined to the electrodes 12a and 12e of the printed circuit board 10, so that the electronic component 1 can be reliably joined to the printed circuit board 10 even if the substrate body 2 on which the electronic component 1 is formed has become warped.

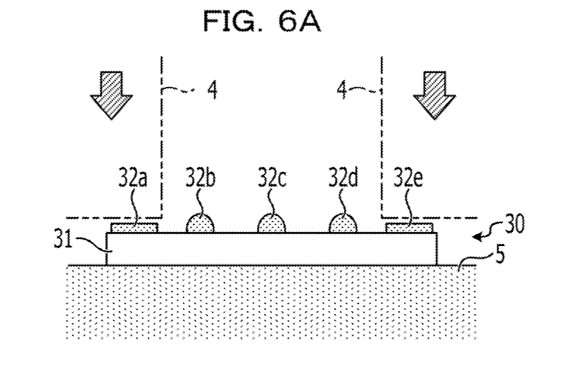

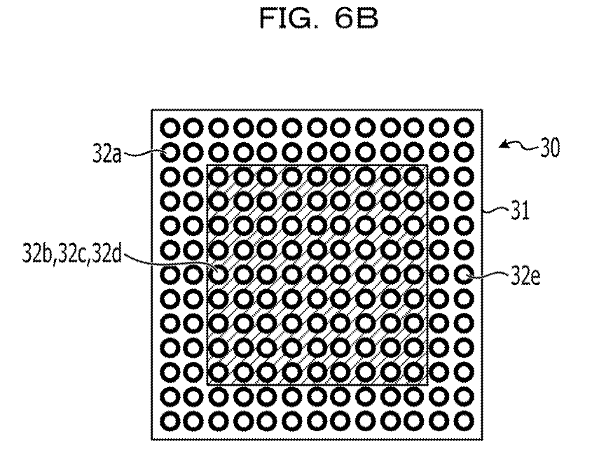

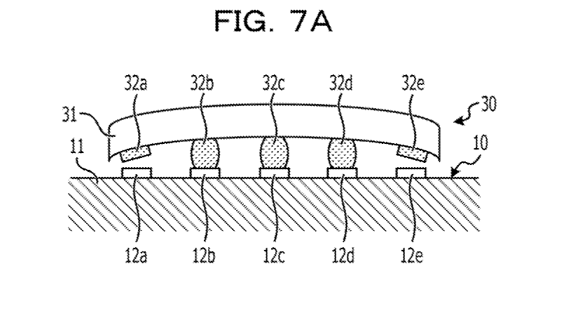

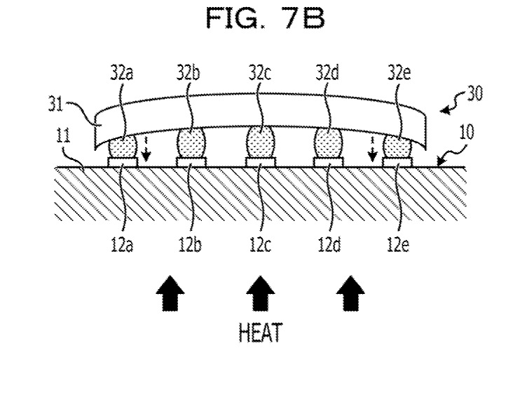

Referring now to FIG. 6A and 6B, the configuration of an electronic component 30 according to a second embodiment will be described. FIG. 6A and FIG. 6B are diagrams each illustrating the configuration of the electronic component according to the second embodiment, where FIG. 6A is a cross-sectional view of the electronic component and FIG. 6B is a plan view thereof. FIG. 7 is a diagram illustrating joints between bumps of an electronic component and electrodes of a printed circuit board.

In the second embodiment, in contrast to the first example, the configuration of the electronic component 30 which is in the form of being inwardly warped by application of heat will be described. In other words, as illustrated in FIG. 6A and FIG. 6B, the bottom surface of the electronic component 30 is one to be warped in a convex shape by application of heat, among bumps 32a to 32e, the bumps 32a and 32e on the peripheral portion of the electronic component 30 (shaded area in FIG. 6A and FIG. 6B) are pressurized and processed to be lower than the heights of the bumps 32b, 32c, and 32d arranged on the center portion of the electronic component 30.

In other words, as illustrated in FIG. 6A and FIG. 6B, the electronic component 30 includes a plate-shaped substrate body 31. In addition, the surface part of the substrate body 3 is provided with a plurality of bumps 32a to 32e which are arranged in a grid. In addition, the electronic component 30 of the second embodiment, which is illustrated in FIG. 6A and FIG. 6B, has its bottom surface to be warped in a convex shape by application of heat. Thus, among the bumps 32a to 32e, the bumps 32a and 32e arranged on the peripheral portion are pressurized to make their heights lower using a press mechanism 4 to reduce their heights.

As illustrated in FIG. 7, when the electronic component 30 is mounted on the printed circuit board 10, the bumps 32b, 32c, and 32d arranged on the inside of the electronic component 30 are solder balls which are not flattened by pressing and brought into contact with the electrodes 12b, 12c, and 12d of the printed circuit board 10.

On the other hand, the bumps 32a and 32e arranged on the outer side of the electronic component 30 are flattened solder balls with lower heights, so that they are spaced from the electrodes 12a and 12e of the printed circuit board and do not contact therewith. Therefore, at the time of reflow-heating, the bumps 32b, 32c, and 32d of the electronic component 30, which are arranged on the peripheral portion thereof, are molten faster than the centrally-located bumps 32a and 32e, so that they can be connected to the electrodes 12b, 12c, and 12d of the printed circuit board 10.

According to the configuration of the electronic component 30 of the second embodiment, even if the peripheral portion of the electronic component 30 is warped downwardly by application of heat, pressing is performed to lower the heights of the solder balls that form the bumps 32a and 32e among the bumps 32a to 32e arranged on the substrate body 31 of the electronic component 30. Therefore, the solder balls of the bumps 32b, 32c, and 32d arranged on the center portion of the electronic component 30 can be respectively joined to the electrodes 12b, 12c, and 12d of the printed circuit board 10, quickly. As a result, in a manner similar to the first embodiment, even if the electronic component 30 is warped by application of heat, the bumps 32a to 32e of the electronic component 30 and the electrodes 12a to 12e of the printed circuit board 10 can be reliably joined to each other.

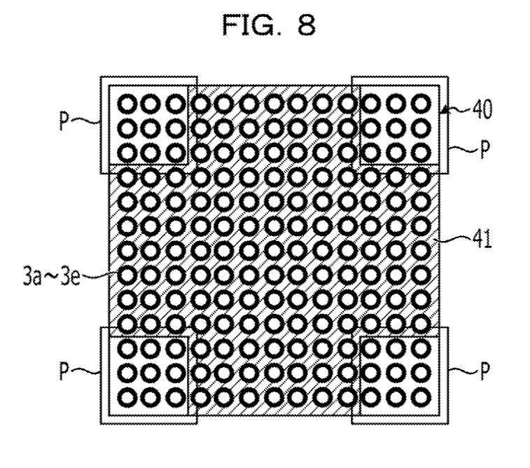

Referring now to FIG. 8, the configuration of an electronic component according to a third embodiment will be described. FIG. 8 is a plan view illustrating the configuration of the electronic component according to the third embodiment. An exemplary electronic component 40 according to the third embodiment will be described as one in which warped portions are distributed at different locations on the electronic component 40 at the time of reflow.

In the third embodiment, assuming the warping direction of the electronic component 40 upon heating, the solder balls are flatten by pressing so as to become lower than the height of the solder balls of the bumps 3a to 3e arranged on highly warped portions.

In other words, as illustrated in FIG. 8, in the case where the substrate body 41 of the electronic component 40 includes four P regions which are highly warped portions, the heights of bumps arranged on an area (slashed area in the figure) other than these P regions are made smaller by flattening under pressure. Therefore, by lowering the heights of the solder balls of bumps arranged on the area (slashed area in the figure) other than the bumps arranged on the highly warped P regions, the solder balls of the bumps on the P regions can be molten faster than those of the slashed area.

Therefore, similar to the electronic component 40 illustrated in FIG. 8, even if the warping of the electronic components 40 is dispersed, bumps other than those arranged on the warped portions are subjected to pressing. Therefore, the bumps 3a to 3e of the electronic component 40 can be reliably joined to the electrodes 12a to 12e of the printed circuit board 10 (FIG. 7).

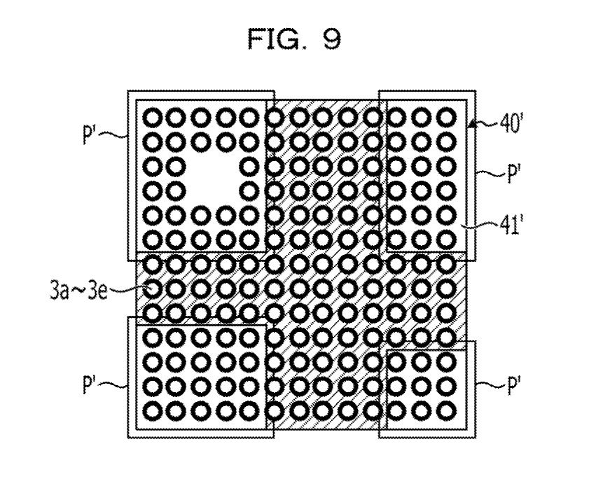

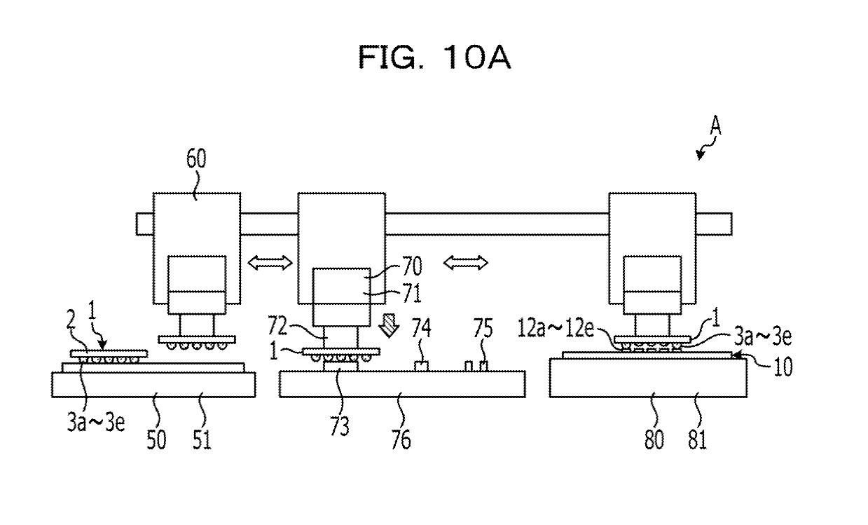

Referring now to FIG. 9, the configuration of an electronic component according to a fourth embodiment will be described. FIG. 9 is a plan view illustrating the configuration of the electronic component according to the fourth embodiment. An exemplary electronic component 40′ according to the fourth embodiment will be described as one in which warped portions are distributed at different locations and different sizes on the electronic component 40′ at the time of reflow.

In the fourth embodiment, assuming the warping direction and area of the electronic component 40′ upon heating, the solder balls of the relevant bumps are flatten by pressing so as to become lower than the height of the solder balls of the bumps 3a to 3e arranged on highly warped portions.

In other words, as illustrated in FIG. 9, in the case where the substrate body 41′ of the electronic component 40′ includes four P′ regions which are highly warped portions with different areas, the heights of bumps arranged on an area (slashed area in the figure) other than these P′ regions are made smaller by flattening under pressure. Therefore, by lowering the heights of the solder balls of bumps arranged on the area (slashed area in the figure) other than the bumps arranged on the highly warped P′ regions, the solder balls of the bumps on the P′ regions can be molten faster than those of the slashed area.

Therefore, similar to the electronic component 40′ illustrated in FIG. 9, even if the warping of the electronic components 40′ is dispersed in different areas, bumps other than those arranged on the warped portions are subjected to pressing. Therefore, the bumps 3a to 3e of the electronic component 40′ can be reliably joined to the electrodes 12a to 12e of the printed circuit board 10 (FIG.

7).

Furthermore, in the first to fourth embodiment, the selection of bumps to be flattened by pressing is based on the warping state of the substrate body 2 and may be performed also in consideration of a package size and the densities of bumps formed on the electronic component and circuit lines connected to the bumps.

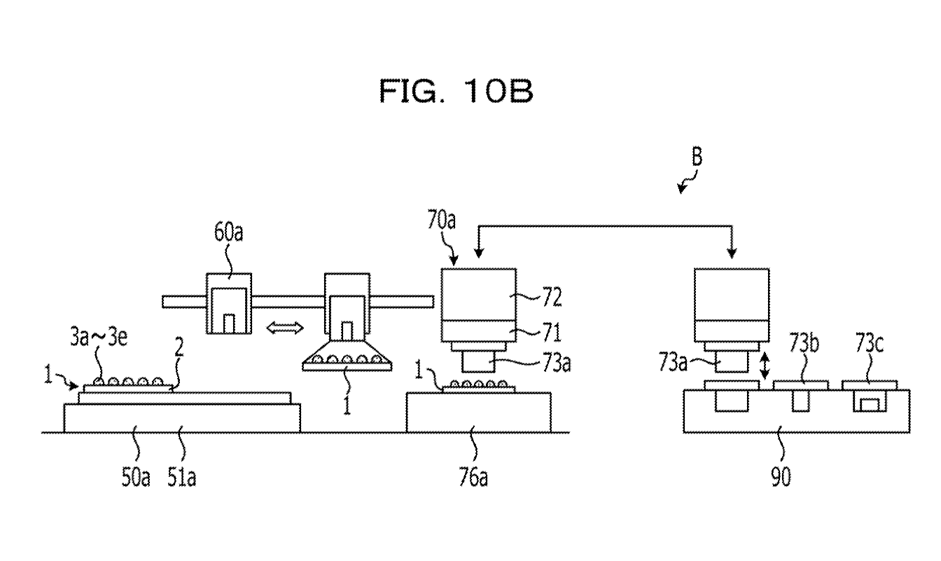

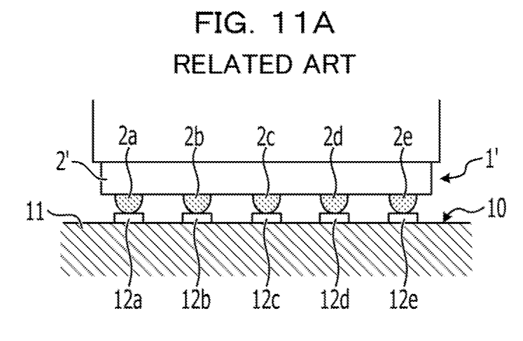

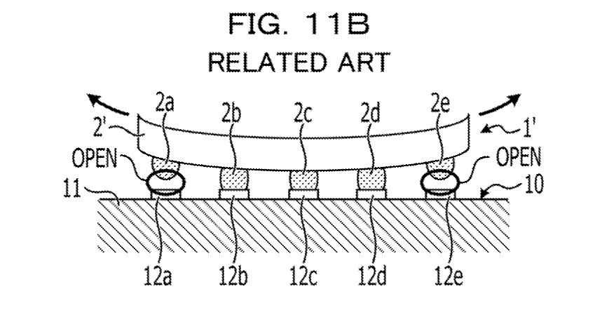

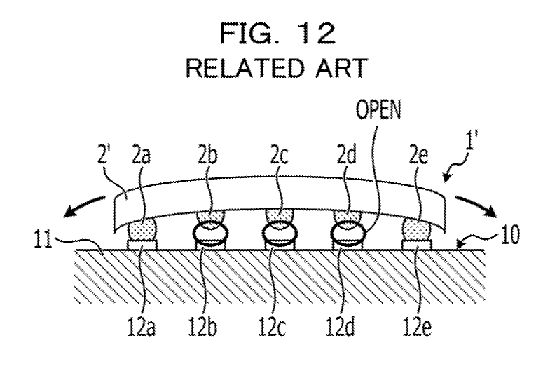

Next, an electronic component mounting apparatus will be described. FIG. 10A is a diagram illustrating the configuration of an electronic component mounting apparatus.

As illustrated in FIG. 10A, the electronic component mounting apparatus A includes an electronic component supplying unit 50, an electronic component transporting unit 60, an electrode pressurizing unit 70, and an electronic component mounting unit 80.

The electronic component supplying unit 50 includes a stage 51 for supplying an electronic component 1. The electronic component 1 utilizes a substrate body 2 with a plurality of bumps 3a to 3e to be arranged on the upper side of the electronic component 1. In addition, the electronic component transporting unit 60 uses its transport mechanism to transport the electronic component 1 placed on the stage 51 of the electronic component supplying unit 50 to the electrode pressurizing unit 70.

The electrode pressurizing unit 70 includes a pressurizing mechanism 71 having a press mechanism 72 and a pressurizing stage 76 having three different convex pressing portions 73, 74, and 75. In the case of pressurizing the bumps 3a to 3e arranged on the substrate body 2 of the electronic component 1 by the press mechanism 72, any of the convex pressing portions 73, 74, and 75 with three different shapes can be suitably selected and used.

The convex pressing portion 73 can flatten two or more solder balls among the bumps 3a to 3e of the electronic component 1 at once. The convex pressing portion 74 can flatten a single solder ball among the bumps 3a to 3e of the electronic component 1. The convex pressing portion 75 can flatten solder balls located at separated positions among the bumps 3a to 3e of the electronic component 1. The widths of the respective convex pressing portions 73, 74, and 75 are smaller than the width of the electronic component 1.

The electronic component mounting unit 80 includes a mounting stage 81 where the printed circuit board 10 is placed on its upper surface. Actually, the electronic component 1, which is mounted on the printed circuit board 10 placed on the upper surface of the mounting stage 81, is reflow-heated. Therefore, the bumps 13a to 13e of the electronic component 1 are molten. Therefore, the bumps 13a to 13e of the electronic component 1 are joined to the electrodes 12a to 12e of the printed circuit board 10, respectively, so that the electronic component 1 can be mounted on the printed circuit board 10.

Next, an electronic component manufacturing apparatus will be described. FIG. 10B is a diagram illustrating the configuration of an electronic component manufacturing apparatus.

As illustrated in FIG. 10B, the electronic component manufacturing apparatus B includes an electronic component supplying unit 50a, an electronic component transporting unit 60a, an electrode pressurizing unit 70a, a pressurizing stage 76a, and a pressurizing-unit replacing unit 90.

The electronic component supplying unit 50a includes a stage 51a for supplying an electronic component 1. The electronic component 1 utilizes a substrate body 2 with a plurality of bumps 3a to 3e to be arranged on the upper side of the electronic component 1. In addition, the electronic component transporting unit 60a uses its transport mechanism to transport the electronic component 1 placed on the stage 51a of the electronic component supplying unit 50a to the electrode pressurizing unit 70a.

The electrode pressurizing unit 70a includes a pressurizing mechanism 72 with a press mechanism 73a. The press mechanism 73a is used for performing pressing to flatten some of bumps 3a to 3e arranged on the substrate body 2 of the electronic component 1. In this case, the bumps 3a to 3e to be flattened can be pressurized by suitably selecting any of three different press mechanisms 73a, 73b, and 73c of the pressurizing-head replacing unit 90.

The width of each of the respective press mechanisms 73a, 74b, and 75c is smaller than the width of the electronic component 1.

In other words, the pressurizing-head replacing unit 90 includes three different press mechanisms 73a, 73b, and 73c, so that any of these three press mechanisms 73a, 73b, and 73c can be suitably selected and used. The press mechanism 73a can be used for flattening two or more solder balls among the bumps 3a to 3e of the electronic component 1 at once.

The press mechanism 73b is used for flattening a single solder ball among the bumps 3a to 3e of the electronic component 1. The press mechanism 73c is used for flattening solder balls located at separated positions among the bumps 3a to 3e of the electronic component 1.

As described above, the electronic component manufacturing apparatus B can suitably select any of three different press mechanisms 73a, 73b, and 73c of the pressurizing-unit replacing unit 90 in response to the warping of the electronic component 1. Therefore, the electronic component 1 on which the bumps 3a to 3e, which can be reliably joined to the electrodes 12a to 12e of the printed circuit board 10, can be manufactured.

All examples and conditional language recited herein are intended for pedagogical objects to aid the reader in understanding the invention and the concepts contributed by the inventors to further the art, and are to be construed as being without limitation to such specifically recited examples and conditions. Although the embodiments of the invention have been described in detail, it will be understood by those of ordinary skill in the relevant art that various changes, substitutions, and alterations could be made hereto without departing from the spirit and scope of the invention as set forth in the claims.

What is claimed is:

1. A manufacturing method of a printed circuit board unit, comprising:
pressing a portion of bumps arranged on an electronic component to lower heights of said portion of bumps as compared to other bumps.

2. The method according to claim 1, wherein said portion of bumps are a plurality of bumps located in a central region on the electronic component.

3. The method according to claim 1, wherein said portion of bumps are a plurality of bumps located in a peripheral region on the electronic component.

4. The method according to claim 1, further comprising applying flux to electrodes of the printed circuit board.

5. The method according to claim 1, further comprising aligning the bumps to corresponding electrodes provided on the printed circuit board.

6. A manufacturing apparatus of a printed circuit board unit, comprising:
a pressing mechanism including a head member configured to press a portion of bumps arranged on an electronic component to lower heights of said portion of bumps as compared to other bumps.

7. The apparatus according to claim 6, wherein the head member has a smaller dimension than the electronic component to be pressed.

8. A manufacturing method of an electronic component, comprising:
providing a plurality of bumps on a substrate body;
pressing a portion of the plurality of bumps to lower heights of said portion of bumps as compared to other bumps.

9. The method according to claim 8, wherein said portion of bumps are a plurality of bumps located in a central region on the electronic component.

10. The method according to claim 8, wherein said portion of bumps are a plurality of bumps located in a peripheral region on the electronic component.

11. An electronic component comprising:
a substrate body; and
a plurality of bumps provided on the substrate body, wherein a portion of the plurality of bumps are configured to have a lower heights than other bumps.

12. The electronic component according to claim 11, wherein said portion of the plurality of bumps are located in a central region on the electronic component.

13. The electronic component according to claim 11, wherein said portion of the plurality of bumps are located in a peripheral region on the electronic component.

14. The electronic component according to claim 11, wherein said portion of the plurality of bumps has substantially a same volume with said other bumps.

15. The electronic component according to claim 11, wherein said portion of the plurality of bumps has a flattened top surface.
